(19) United States
(12) Patent Application Publication
(10) Pub. No.: US 2025/0132296 A1
(43) Pub. Date: Apr. 24, 2025

(54) SEMICONDUCTOR PACKAGE AND MANUFACTURING METHOD THEREOF

(71) Applicant: Taiwan Semiconductor Manufacturing Company, Ltd., Hsinchu (TW)

(72) Inventors: Hsien-Wei Chen, Hsinchu City (TW); Meng-Liang Lin, Hsinchu (TW); Shin-Puu Jeng, Hsinchu (TW)

(73) Assignee: Taiwan Semiconductor Manufacturing Company, Ltd., Hsinchu (TW)

(21) Appl. No.: 18/493,768

(22) Filed: Oct. 24, 2023

(51) Int. Cl. H01L 25/10; H01L 21/56; H01L 23/00; H01L 23/31; H01L 23/498; H01L 23/538; H01L 25/065

(52) U.S. Cl. CPC H01L 25/105; H01L 21/565; H01L 23/3107; H01L 23/49822; H01L 23/49838; H01L 23/5381; H01L 24/08; H01L 24/16; H01L 24/32; H01L 24/73; H01L 24/80; H01L 25/0652; H10D 1/68; H01L 2224/08145; H01L 2224/16227; H01L 2224/16238; H01L 2224/32225; H01L 2224/73204; H01L 2224/80895; H01L 2224/80896; H01L 2225/1023; H01L 2225/1041; H01L 2225/1058; H01L 2924/15174

(57) ABSTRACT

A semiconductor package includes an interposer including a first redistribution structure, a first semiconductor die electrically coupled to the first redistribution structure through conductive joints, and a first encapsulant disposed on the first redistribution structure and laterally covering the first semiconductor die. The first semiconductor die includes a semiconductor substrate including a first side facing the first redistribution structure and a second side opposite to the first side, a through substrate via provided within the semiconductor substrate, and a passive device disposed between the second side of the semiconductor substrate and the conductive joints.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a tendency for smaller and more creative packaging techniques of semiconductor dies has emerged. Although existing semiconductor package and manufacturing method thereof have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B illustrate schematic semiconductor dies, in accordance with some embodiments.

FIGS. 2A through 2H illustrate schematic cross-sectional views of intermediate steps during a process for forming a semiconductor package, in accordance with some embodiments.

FIGS. 3A and 3F illustrate schematic cross-sectional views of intermediate steps during a process for forming a semiconductor package, in accordance with some embodiments.

FIG. 4 illustrates a schematic cross-sectional view of a semiconductor package, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, terms, such as “first,” “second,” “third,” “fourth,” “fifth,” “sixth,” and the like, may be used herein for ease of description to describe similar or different element(s) or feature(s) as illustrated in the figures, and may be used interchangeably depending on the order of the presence or the contexts of the description.

Embodiments discussed herein may be discussed in a specific context, namely a semiconductor package (e.g., an integrated fan-out (InFO) package, a chip-on-wafer-on-substrate (CoWoS) package, or the like) having one or more semiconductor dies vertically stacked and connected to effectively form a semiconductor package. In some embodiments, the semiconductor dies include capacitors, such as deep trench capacitors (DTCs), metal-oxide-metal capacitors, metal-insulator-metal capacitors, the like, or an integrated passive device (IPD), a combination thereof etc. In some embodiments, the semiconductor dies include a local interconnect device which provides electrical connection between the overlying semiconductor dies and increases the communication bandwidth between the overlying semiconductor dies.

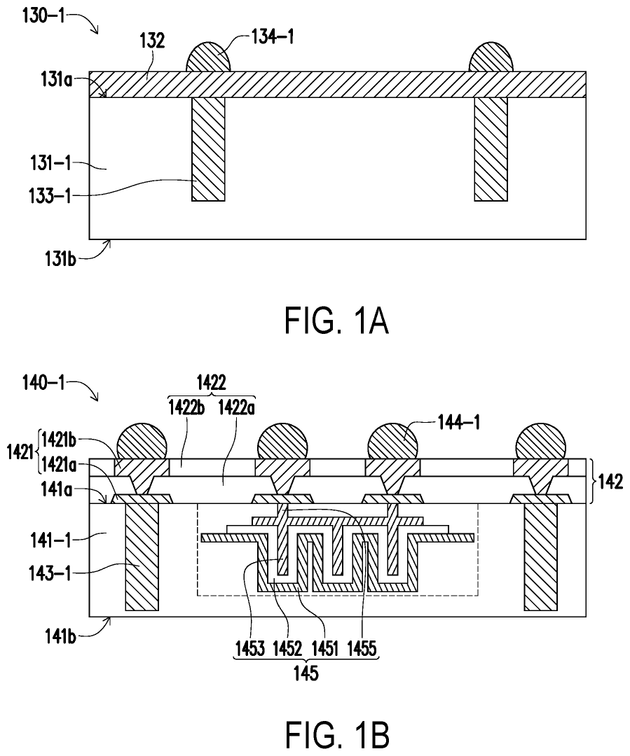

FIGS. 1A and 1B illustrate schematic semiconductor dies according to some embodiments. It should be noted that the above examples in FIGS. 1A and 1B are provided for illustrative purposes only, and the semiconductor dies may utilize fewer or additional elements according to alternative embodiments.

Referring to FIG. 1A, a first semiconductor die 130-1 is provided. The first semiconductor die 130-1 may be formed in a semiconductor wafer, which may include different die regions that are singulated in subsequent steps to form a plurality of first semiconductor dies 130-1. The first semiconductor die 130-1 may be processed according to applicable manufacturing processes to form integrated circuits. For example, the first semiconductor die 130-1 includes a first semiconductor substrate 131-1, such as silicon, doped or undoped, or an active layer of a silicon-on-insulator (SOI) substrate. The first semiconductor substrate 131-1 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other semiconductor substrates, such as multi-layered or gradient substrates, may be used. The first semiconductor substrate 131-1 includes a front side 131a and a backside 131b opposite to the front side 131a.

Devices (not individually shown) may be formed in/on the front side 131a of the first semiconductor substrate 131-1. The devices may be active devices (e.g., transistors, diodes, or the like), capacitors, resistors, or the like. An inter-layer dielectric (ILD; not individually shown) may be formed over the front side 131a of the first semiconductor substrate 131-1 to surround and cover the devices. Conductive plugs (not individually shown) may extend through the ILD to electrically and physically couple the devices. For example, when the devices are transistors, the conductive plugs couple the gates and source/drain regions of the transistors. Alternatively, the devices and the conductive plugs are omitted in the first semiconductor die 130-1. The first semiconductor die 130-1 may include a first interconnect structure 132 formed over the ILD and the conductive plugs to interconnect the devices so as to form an integrated circuit. For example, the first interconnect structure 132 is formed by interconnect wirings (not individually shown) embedded in interconnect dielectric layers. The interconnect wirings electrically coupled to the devices by the conductive plugs may include conductive pads, conductive lines, and conductive vias. The interconnect dielectric layers may include one or more low-k dielectric layers.

The first semiconductor die 130-1 may include one or more first through substrate vias (TSVs) 133-1 extending from the front side 131a of the first semiconductor substrate 131-1 toward the backside 131b of the first semiconductor substrate 131-1. The first TSVs 133-1 may be formed in the trenches of the first semiconductor substrate 131-1 by depositing one or more diffusion barrier layer(s) or isolation layer(s), depositing a seed layer, and depositing a conductive material (e.g., tungsten, titanium, aluminum, copper, any combinations thereof and/or the like) into the trenches of the first semiconductor substrate 131-1. For example, the respective first TSV 133-1 has one end that is buried in the first semiconductor substrate 131-1 at this stage.

In some embodiments, the first semiconductor die 130-1 includes first die connectors 134-1 formed over the first interconnect structure 132. The first die connectors 134-1 may be electrically coupled to the first TSVs 133-1 and the devices (not individually shown) through the first interconnect structure 132. In some embodiments, the first die connectors 134-1 are micro-bumps. The first die connectors 134-1 may be or include ball grid array (BGA) connectors, solder balls, metal pillars, controlled collapse chip connection (C4) bumps, electroless nickel-electroless palladium-immersion gold (ENEPIG) technique formed bumps, or the like. The first die connectors 134-1 may include a conductive material such as solder, copper, aluminum, gold, nickel, silver, palladium, tin, the like, or a combination thereof. In some embodiments, the first die connectors 134-1 are solder bumps. In some embodiments, the respective first die connector 134-1 includes a metallic pillar overlying the first interconnect structure 132 and a cap layer (e.g., solder cap) overlying the metallic pillar. The metallic pillar may be a copper-containing layer. In some embodiments, the metallic pillar includes a nickel-containing layer formed on the copper-containing layer to serve as a diffusion barrier which blocks copper diffusion from the copper-containing layer to the solder cap. For example, the metallic pillar includes copper, nickel, tin, tin-lead, gold, silver, platinum, palladium, Indium, nickel-palladium-gold, nickel-gold, alloys, etc.

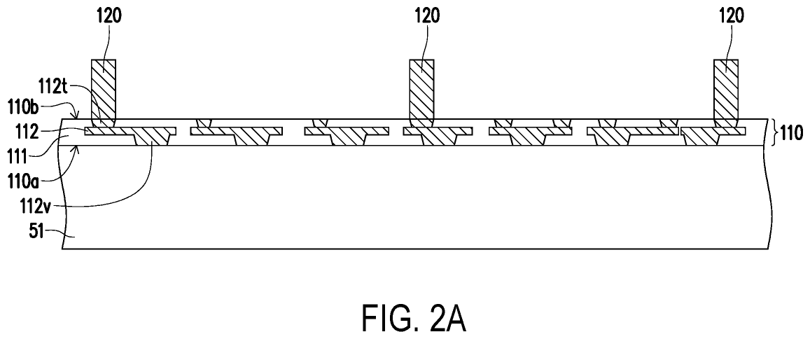

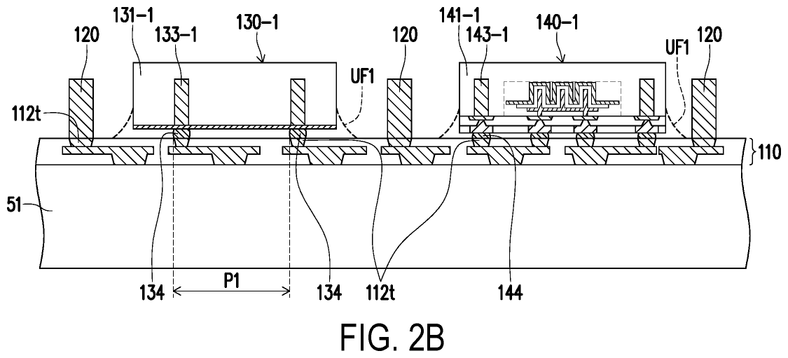

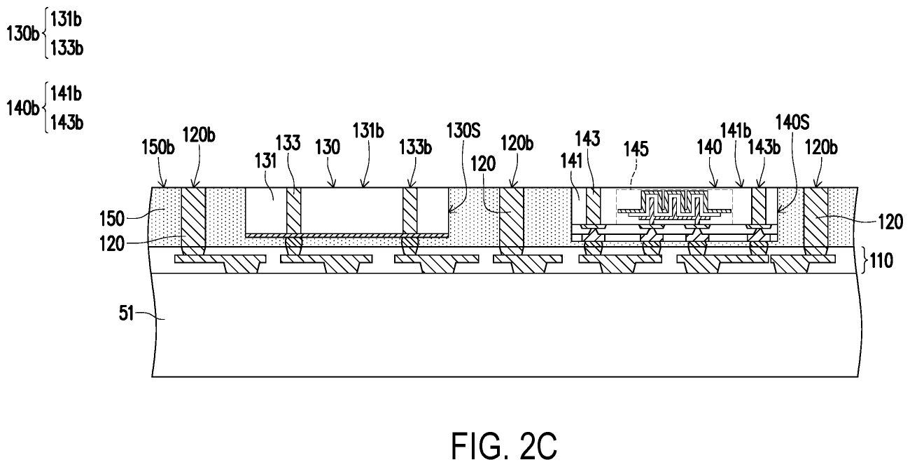

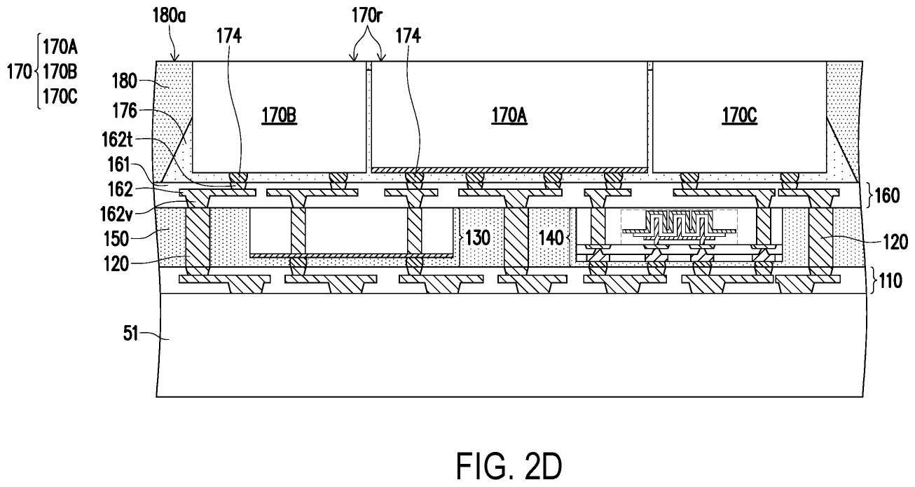

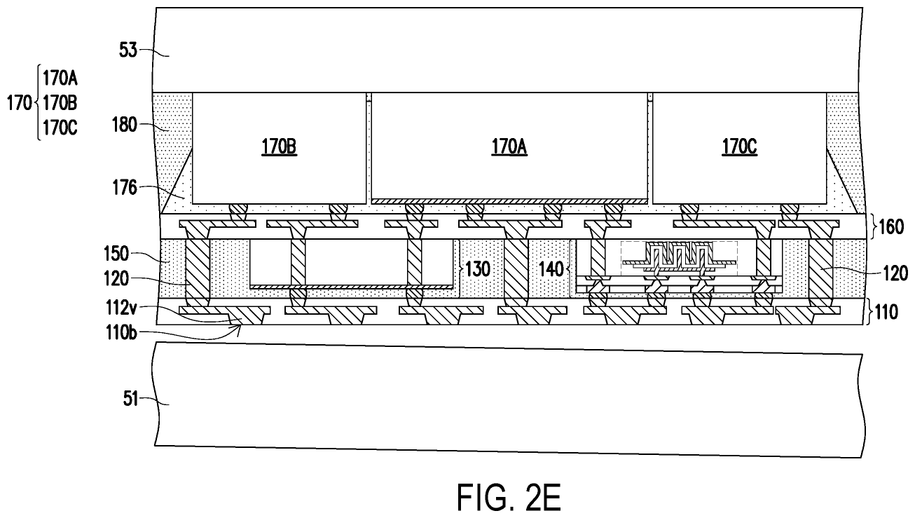

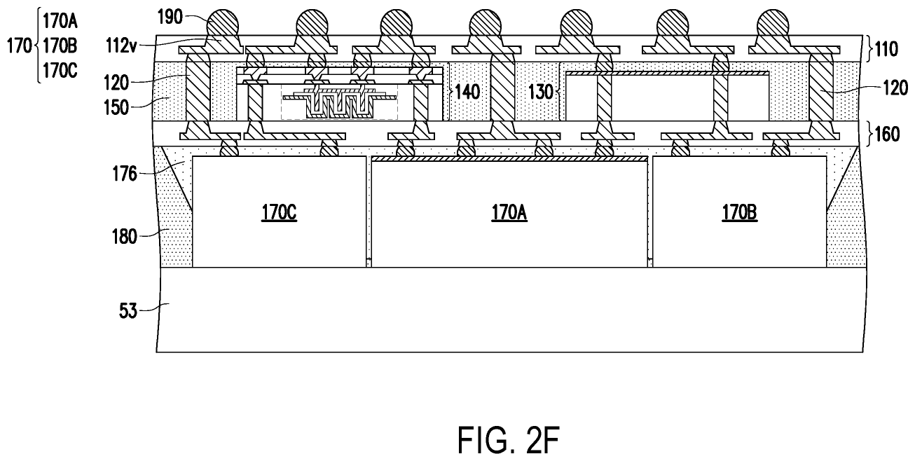

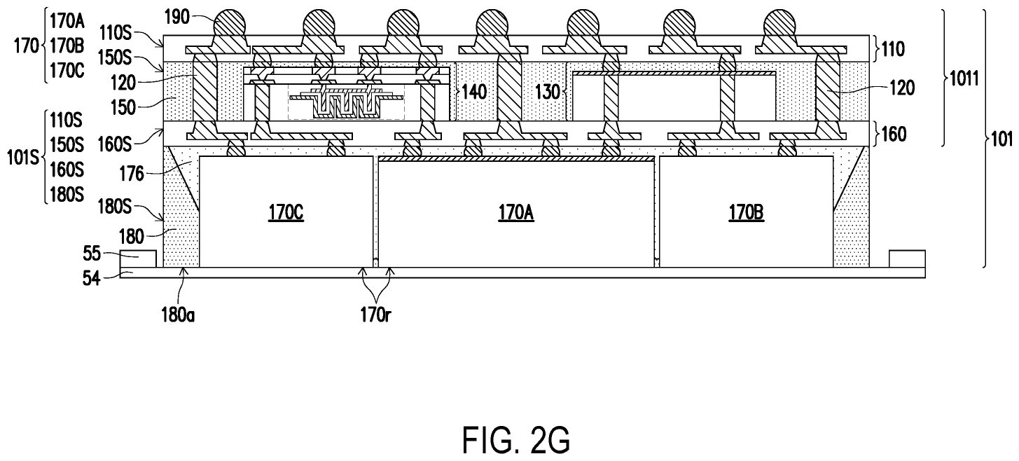

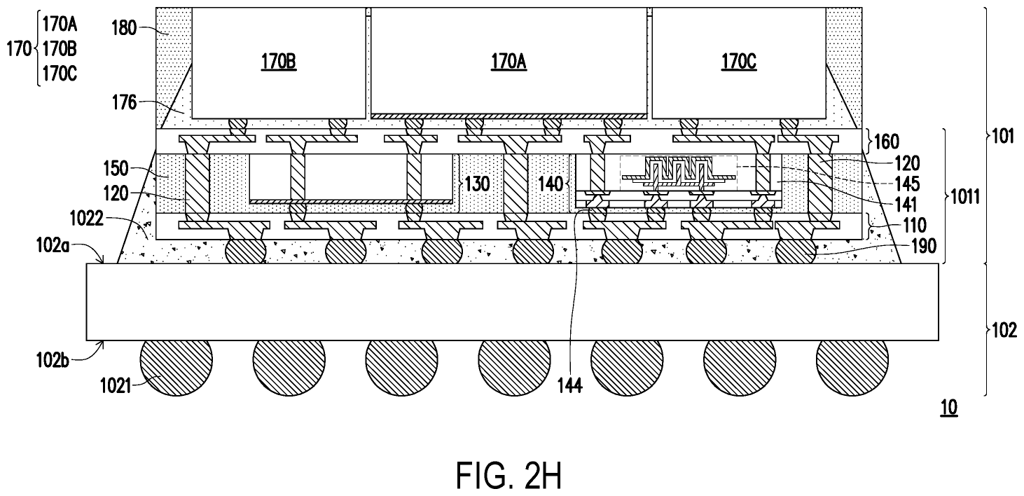

The first semiconductor die 130-1 may be a logic device (e.g., central processing unit (CPU), graphics processing unit (GPU), microcontroller, etc.), a memory device (e.g., dynamic random access memory (DRAM) die, static random access memory (SRAM) die, etc.), a power management device (e.g., power management integrated circuit (PMIC) die), a radio frequency (RF) device, a sensor device, a micro-electro-mechanical-system (MEMS) device, a signal processing device (e.g., digital signal processing (DSP) die), a front-end device (e.g., analog front-end (AFE) dies), a combination thereof (e.g., a system-on-a-chip (SoC) die), and/or the like. In some embodiments, the first semiconductor die 130-1 is a bridge die. For example, the first semiconductor die 130-1 is a local interconnect device which may provide electrical connection between the subsequently-mounted third semiconductor dies (170 labeled in FIG. 2D) and increases the communication bandwidth therebetween. In some embodiments, the first semiconductor die 130-1 is free of active and/or passive devices.

Referring to FIG. 1B and with reference to FIG. 1A, a second semiconductor die 140-1 is provided. The second semiconductor die 140-1 may be similar to the first semiconductor die 130-1. For example, the second semiconductor die 140-1 is formed in a semiconductor wafer, which may include different die regions that are singulated in subsequent steps to form a plurality of second semiconductor dies 140-1. The second semiconductor die 140-1 may be processed according to applicable manufacturing processes to form integrated circuits. For example, the second semiconductor die 140-1 includes a second semiconductor substrate 141-1. The material of the second semiconductor substrate 141-1 may be similar to the first semiconductor substrate 131-1. The second semiconductor substrate 141-1 includes a front side 141a and a backside 141b opposite to the front side 141a. Devices (e.g., transistors, diodes, capacitors, resistors, or the like; not individually shown) may (or may not) be formed in/on the front side 141a of the second semiconductor substrate 141-1. Conductive plugs may (or may not) be formed to electrically and physically couple the devices.

The second semiconductor die 140-1 may include a second interconnect structure 142 formed over the front side 141a of the second semiconductor substrate 141-1 and may interconnect the devices (if present) to form an integrated circuit. For example, the second interconnect structure 142 is formed by interconnect wirings 1421 embedded in interconnect dielectric layers 1422. The interconnect wirings 1421 may include conductive pads, conductive lines, and conductive vias. The interconnect dielectric layers 1422 may include one or more low-k dielectric layers or any suitable dielectric material. In the illustrated embodiment, the interconnect wirings 1421 includes a lower wiring 1421a and an upper wiring 1421b formed on and connected to the lower wiring 1421a, and the interconnect dielectric layers 1422 includes a lower layer 1422a covering the lower wiring 1421a and an upper layer 1422b formed on the lower layer 1422a and covering the upper wiring 1421b. It should be noted that the number of the interconnect wirings 1421 and the number of the interconnect dielectric layers 1422 are merely examples and construe no limitation in the disclosure.

The second semiconductor die 140-1 may include one or more second TSVs 143-1 extending from the front side 141a of the second semiconductor substrate 141-1 toward the backside 141b of the second semiconductor substrate 141-1. The second TSVs 143-1 may be similar to the first TSVs 133-1. In some embodiments, the respective second TSV 143-1 has one end connected to the lower wiring 1421a (e.g., conductive pads) and an opposing end buried in the second semiconductor substrate 141-1 at this stage. In some embodiments, the second semiconductor die 130-1 includes second die connectors 144-1 formed on the upper wiring 1421b (e.g., (e.g., conductive pads). The second die connectors 144-1 may be similar to the first die connectors 134-1.

With continued reference to FIG. 1B, the second semiconductor die 140-1 may include one or more passive devices (e.g., capacitor 145) embedded therein. For example, the capacitor 145 is embedded in the second semiconductor substrate 141-1. In alternative embodiments, the capacitor 145 is embedded in the interconnect dielectric layers 1422. In some embodiments, the capacitor 145 includes a first conductive layer 1451 (or a first electrode), a second conductive layer 1453 (or a second electrode), and a dielectric layer 1452 sandwiched therebetween to separate the first conductive layer 1451 from the second conductive layer 1453. In some embodiments, conductive contacts 1455 of the capacitor 145 couple the second conductive layer 1453 and/or the first conductive layer 1451 to the lower wiring 1421a of the second interconnect structure 142.

In some embodiments, the first conductive layer 1451, the second conductive layer 1453, and/or the conductive contacts 1455 may include a conductive material, such as tantalum, tantalum nitride, titanium, titanium nitride, or the like, and may be formed by CVD, PVD, or the like. The first conductive layer 1451 and the second conductive layer 1453 may have the same material or different materials. The dielectric layer 1452 may include a high-k dielectric material (e.g., hafnium oxide, zirconium oxide, aluminum oxide, tantalum oxide, etc.), any suitable dielectric(s), any combination thereof, or the like. In one embodiment, the capacitor 145 is a trench capacitor such as a DTC. In one embodiment, the capacitor 145 is an IPD having capacitor trench that is filled by at least conductive material. In one embodiment, the capacitor 145 is a metal-insulator-metal (MIM) capacitor or a metal-oxide-metal (MOM) capacitor. Due to the capacitor 145 embedded in the second semiconductor die 140-1, the power integrity and system performance of the second semiconductor die 140-1 are improved. The numbers of the capacitor 145 may be designated based on the demand and/or design layout, and the disclosure is not limited thereto.

FIGS. 2A through 2H illustrate schematic cross-sectional views of intermediate steps during a process for forming a semiconductor package, in accordance with some embodiments. Unless specified otherwise, like reference numerals in the present embodiment represent like components in the embodiment shown in FIGS. 1A and 1B. Although method embodiments are discussed as being performed in a particular order, other embodiments may be performed in any logical order.

Referring to FIG. 2A, a first redistribution structure 110 may be formed over a first temporary carrier 51, and conductive pillars 120 may be formed on the first redistribution structure 110. For example, the material of the first temporary carrier 51 includes glass, silicon, metal, ceramic, combinations thereof, multi-layers thereof, or the like. In some embodiments, the first temporary carrier 51 is provided with a release layer (not individually shown). For example, the release layer includes a light-to-heat-conversion (LTHC) release coating which reduces or loses its adhesiveness when exposed to a radiation source (e.g., ultra-violet light or a laser). In some embodiments, the release layer includes any acceptable adhesive material. In some embodiments, a first side 110a of the first redistribution structure 110 is disposed on the release layer, and the conductive pillars 120 are disposed on the second side 110b of the first redistribution structure 110 opposite to the first side 110a.

In some embodiments, the first redistribution structure 110 includes one or more first dielectric layers 111 and one or more first conductive patterns 112 formed in/on the first dielectric layers 111. The material(s) of the first dielectric layers 111 may include electrically insulating materials such as polymer (e.g., polyimide (PI), polybenzoxazole (PBO), benzocyclobutene (BCB), etc.), or any suitable dielectric material. The first conductive patterns 112 may include conductive vias, conductive pads, and conductive lines which are collectively referred to as redistribution lines. The first conductive patterns 112 may be formed from conductive material(s) such as copper, aluminum, gold, nickel, silver, palladium, tin, alloy, the like, a combination thereof, etc. In some embodiments, the outermost conductive pattern 112v (e.g., conductive vias) of the first conductive patterns 112 is formed over the first temporary carrier 51 for the further electrical connection. It should be noted that the number of the first dielectric layers 111 and the number of the first conductive patterns 112 may be selected based on demand and are not limited in the disclosure.

With continued reference to FIG. 2A, the conductive pillars 120 formed on the first redistribution structure 110 may be physically and electrically connected to the topmost conductive pattern 112t. As an example, to form the conductive pillars 120, a photoresist (not shown) is formed and patterned on the first redistribution structure 110, where the pattern of the photoresist corresponds to conductive pillars 120. The patterning forms openings through the photoresist to expose at least a portion of the topmost conductive pattern 112t (e.g., conductive vias or conductive pads) at the second side 110b of the first redistribution structure 110. One or more conductive materials (e.g., copper, titanium, tungsten, aluminum, alloy, and/or the like) may be formed in the openings of the photoresist. The photoresist may then be removed. The remaining portions of the conductive material(s) on the second side 110b of the first redistribution structure 110 form the conductive pillars 120. In alternative embodiments, the conductive pillars 120 are pre-formed and placed over the first redistribution structure 110.

Referring to FIG. 2B with reference to FIG. 2A and FIGS. 1A-1B, one or more first semiconductor die(s) 130-1 may be disposed on and electrically coupled to the first redistribution structure 110. A group of the conductive pillars 120 may surround the respective first semiconductor die 130-1. In some embodiments, the respective first semiconductor die 130-1 are picked and placed on the first redistribution structure 110. For example, the first die connectors 134-1 of the respective first semiconductor die 130-1 are disposed on the topmost conductive pattern 112t and one or more reflow operation(s) may be performed to reflow the first die connectors 134-1 to form first conductive joints 134. For example, thermal operations are performed to melt solder material of the first die connectors 134-1 and produce generally round solder joints. The respective first semiconductor die 130-1 may be electrically coupled to the first redistribution structure 110 through the first conductive joints 134. In some embodiments, a pitch P1 between adjacent two of the first conductive joints 134 is in a range of about 10 μm and about 120 μm, inclusive. Other suitable values of the pitch P1 may be possible. In some embodiments, the first TSVs 133-1 remain buried in the first semiconductor substrate 133-1 at this stage.

In some embodiments, one or more second semiconductor die(s) 140-1 may be disposed on the first redistribution structure 110 through a pick-and-place process and may be electrically coupled to the first redistribution structure 110 through second conductive joints 144. The coupling of the second semiconductor die 140-1 to the first redistribution structure 110 may be similar to the process of coupling the first semiconductor die 130-1 to the first redistribution structure 110. For example, the second die connectors 144-1 of the respective second semiconductor die 140-1 are disposed on the topmost conductive pattern 112t of the first redistribution structure 110, and a reflow process may be performed to form the second conductive joints 144 coupling the second semiconductor die 140-1 to the topmost conductive pattern 112t. The reflow process on the first and second die connectors (134-1 and 144-1) may (or may not) be performed simultaneously. The size and/or the pitch of the second conductive joints 144 may be similar to (or different from) those of the first conductive joints 134. Another group of the conductive pillars 120 may surround the respective second semiconductor die 140-1. The second TSVs 143-1 may remain buried in the second semiconductor substrate 143-1 at this stage.

Still referring to FIG. 2B, an underfill (UF1 illustrated in the dashed lines) may be formed in a gap between the first redistribution structure 110 and the respective first semiconductor die 130-1 to laterally surround the first conductive joints 134 for protection. Similarly, another underfill (illustrated in the dashed lines) may be formed in a gap between the first redistribution structure 110 and the respective second semiconductor die 140-1 to laterally surround the second conductive joints 144. Depending on the applied amount of the underfill material, a portion of the underfill may climb upward to cover at least a lower portion of the sidewall(s) of the first/second semiconductor die(s). Alternatively, the underfill is omitted so that the underfill is illustrated in the dashed lines in FIG. 2B to indicate it may or may not exist.

Referring to FIG. 2C with reference to FIG. 2B, a first encapsulant 150 may be formed on the first redistribution structure 110 to laterally cover the conductive pillars 120 and the first and second semiconductor dies 130 and 140 (and the underfill, if present). The first encapsulant 150 may be or include molding compound, molding underfill, epoxy resin, or the like, and may be applied by compression molding, transfer molding, or the like. In some embodiments, the first encapsulant 150 is formed by: forming a layer of encapsulating material on the first redistribution structure 110 to bury the conductive pillars 120 and the first and second semiconductor dies 130 and 140; curing the encapsulating material; and optionally performing a planarization process (e.g., chemical mechanical polishing (CMP), grinding, etching, a combination thereof, etc.) on the encapsulating material to level the encapsulating material with the conductive pillars 120 and the first and second semiconductor dies 130 and 140. In some embodiments where the underfill UF1 is not formed, the first encapsulant 150 may be a molding underfill which extends along the sidewalls (130S and 140S) of the first and second semiconductor dies (130 and 140) and also extends into a gap between the first redistribution structure 110 and the respective first/second semiconductor die 130/140 to surround the first/second conductive joints 134/144. In some embodiments, the conductive pillars 120 penetrating through the first encapsulant 150 (e.g., the molding layer) may be referred to as through molding vias (TMVs) or through interlayer vias (TIVs).

With continued reference to FIG. 2C and FIG. 2B, during the formation of the first encapsulant 150 (e.g., the planarization process), the first and/or second semiconductor dies 130 and/or 140 may be thinned down to be substantially leveled with the first encapsulant 150 and the TMVs 120. For example, the surface 150b of the first encapsulant 150 and the surfaces 120b of the TMVs 120 are substantially leveled (or coplanar) with the backside 130b of the respective first semiconductor die 130 and the backside 140b of the respective second semiconductor die 140, within process variations. In some embodiments, during the formation of the first encapsulant 150 (e.g., the planarization process), the first semiconductor substrate 133-1 is thinned down to form the first semiconductor substrate 133 having the backside 131b, and the backside 131b is substantially leveled (or coplanar) with the surfaces 133b of the first TSVs 133, within process variations. The backside 131b of the first semiconductor substrate 133 and the surfaces 133b of the first TSVs 133 may be collectively viewed as the backside 130b of the first semiconductor die 130. Similarly, the second semiconductor substrate 143-1 may be thinned down to form the second semiconductor substrate 143 having the backside 141b, and the backside 141b is substantially leveled (or coplanar) with the surfaces 143b of the second TSVs 143, within process variations. The backside 141b of the second semiconductor substrate 143 and the surfaces 143b of the second TSVs 143 may be collectively viewed as the backside 140b of the second semiconductor die 140. In some embodiments, after forming the first encapsulant 150, the capacitor 145 remains buried in the second semiconductor substrate 143. The second semiconductor substrate 143 may protect the capacitor 145 from damage during the planarization process.

Referring to FIG. 2D with reference to FIG. 2C, a second redistribution structure 160 may be formed on the first encapsulant 150, the TMVs 120, and the first and second semiconductor dies 130 and 140. In some embodiments, the second redistribution structure 160 includes one or more second dielectric layers 161 and one or more second conductive patterns 162 formed in/on the second dielectric layers 161 to be electrically coupled to the TMVs 120 and the first and second semiconductor dies 130 and 140. The materials of the second dielectric layers 161 and the second conductive patterns 162 may be similar to those of the first dielectric layers 111 and the first conductive patterns 112 of the first redistribution structure 110, respectively. The second conductive patterns 162 may include conductive vias, conductive pads, and conductive lines which are collectively referred to as redistribution lines. In some embodiments, the first redistribution structure 110 connected to the first/second semiconductor die 130/140 through the first/second conductive joints 134/144 is referred to as a front side redistribution structure, and the second redistribution structure 150 connected to the backside 130b/140b of the first/second semiconductor die 130/140 is referred to as a backside redistribution structure.

In some embodiments, the bottommost conductive vias 162v of the second conductive patterns 162 formed in the openings of the bottommost one of the second dielectric layers 161 may directly land on the TMVs 120, the first TSVs 133, and the second TSVs 143. The tapering direction of the conductive vias in the second redistribution structure 160 may be the same as the tapering direction of the conductive vias in the first redistribution structure 110. For example, the conductive vias in the second redistribution structure 160 are tapered in a direction toward the TMVs 120 and the first and second semiconductor dies 130 and 140, and the conductive vias in the first redistribution structure 110 are tapered in a direction from the TMVs 120 and the first and second semiconductor dies 130 and 140. It should be noted that the number of the second dielectric layers 161 and the number of the second conductive patterns 162 may be selected based on demand and are not limited in the disclosure.

With continued reference to FIG. 2D, one or more third semiconductor dies 170 may be disposed on and electrically coupled to the second redistribution structure 160. The third semiconductor dies 170 may be electrically coupled to the TMVs 120, the first semiconductor die 130, and the second semiconductor die 140 through the second conductive patterns 162 of the second redistribution structure 160. The respective third semiconductor die 170 (e.g., 170A, 170B, 170C) may be or include a logic die (e.g., central processing unit (CPU), graphics processing unit (GPU), system-on-a-chip (SoC), application processor (AP), microcontroller, etc.), a memory die (e.g., high bandwidth memory (HBM) die, hybrid memory cube (HMC) die, dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), a voltage regulator die, a combination thereof, and/or the like. The third semiconductor dies (170A, 170B, and 170C) may be the same type of die or may be different types of dies. In an embodiment, the third semiconductor die 170A is a logic die (e.g., a SoC die), the third semiconductor die 170B is a memory die (e.g., a HBM die), and the third semiconductor die 170C is a passive die (e.g., a DTC die). It should be noted that although the number and the type of the third semiconductor dies 170 may vary depending on the product requirements.

In some embodiments, the respective third semiconductor die 170 is coupled to the topmost second conductive pattern 162t (e.g., conductive vias or UBM pads) of the second redistribution structure 160 through third conductive joints 174. The third conductive joints 174 may be formed from conductive materials such as solder, copper, aluminum, gold, nickel, silver, the like, or a combination thereof. In some embodiments, the third conductive joints 174 are solder joints. In some embodiments, a first underfill 176 is formed in a gap between the second redistribution structure 160 and the third semiconductor dies 170 to surround the third conductive joints 174. In some embodiments, the first underfill 176 continuously extends between adjacent two of the third semiconductor dies 170. In some embodiments, the first underfill 176 includes discrete portions, and each portion of the first underfill 176 surrounds one of the third semiconductor dies 170. The first underfill 176 may be formed by a capillary flow process after the third semiconductor dies 170 are attached or may be formed by a suitable deposition method before the third semiconductor dies 170 are attached. A curing process may be performed to solidity the underfill material so as to form the first underfill 176. Alternatively, the first underfill 176 is omitted.

Still referring to FIG. 2D, a second encapsulant 180 may be formed on the second redistribution structure 160 to at least laterally cover the third semiconductor dies 170 and the first underfill 176. The material and the forming process of the second encapsulant 180 may be similar to those of the first encapsulant 150 described in FIG. 2C, and thus the detailed descriptions are not repeated herein. In some embodiments where the first underfill 176 is omitted, the second encapsulant 180 is a molding underfill which fills the space that is filled by the first underfill 176. The rear surface 170r of the respective third semiconductor die (170A, 170B or 170C) may (or may not) be accessibly exposed by the second encapsulant 180. For example, the planarization process is performed to level the surface 180a of the second encapsulant 180 and the rear surface(s) 170r of the third semiconductor die(s) 170. The rear surface(s) 170r of the third semiconductor die(s) 170 may (or may not) be covered by the second encapsulant 180.

Referring to FIG. 2E with reference to FIG. 2D, the first temporary carrier 51 may be de-bonded from the first redistribution structure 110. In some embodiments where the first temporary carrier 51 is provided with the LTHC layer (not shown), the de-bonding of the first temporary carrier 51 includes projecting a light (e.g., laser light or UV light) on the release layer, so that the release layer decomposes under the heat of the light and the first temporary carrier 51 and the release layer are removed. In some embodiments where the first temporary carrier 51 is provided with an adhesive layer (not shown), a suitable solvent may be used to dissolve the adhesive layer. In some embodiments, the first temporary carrier 51 is removed through stripping, peeling, etching, a combination thereof, etc. In some embodiments, a second temporary carrier 53 is attached to the second encapsulant 180 and the third semiconductor dies 170 (if the rear surfaces 170r are exposed by the second encapsulant 180). The second temporary carrier 53 may be similar to the first temporary carrier 51. In some embodiments, the second temporary carrier 53 is provided with a release layer (not shown) to facilitate releasing the second temporary carrier 53 from the resulting structure in the subsequent process. Alternatively, the release layer is omitted. In some embodiments, after the first temporary carrier 51 is removed, the second side 110b of the first redistribution structure 110 is revealed. For example, the outermost conductive pattern 112v of the first conductive patterns 112 is accessibly exposed for further electrical connection.

Referring to FIG. 2F with reference to FIG. 2E, conductive terminals 190 may be formed on the outermost conductive pattern 112v of the first redistribution structure 110. In some embodiments, the outermost conductive pattern 112v includes conductive vias, and the conductive terminals 190 are directly formed on the conductive vias so that the additional steps (e.g., forming a photoresist for UBM pads, forming UBM pads, and removing the photoresist, etc.) can be skipped. In some embodiments, the outermost conductive pattern 112v includes UBM pads, and the conductive terminals 190 are directly formed on the UBM pads. In alternative embodiments, UBM pads (not shown) are formed on the outermost conductive pattern 112v (e.g., conductive vias) after de-bonding the first temporary carrier 51, and then the conductive terminals 190 are formed on the UBM pads. The conductive terminals 190 may include one or more conductive material(s) such as solder, copper, aluminum, gold, nickel, silver, palladium, tin, alloy, the like, or a combination thereof. In some embodiments, the conductive terminals 190 include BGA connectors, solder balls, metal pillars, C4 bumps, micro-bumps, ENEPIG bumps, or the like. For example, the conductive terminals 190 are C4 bumps.

Referring to FIG. 2G with reference to FIG. 2F, the second temporary carrier 53 may be de-bonded from the overlying structure. The de-bonding of the second temporary carrier 53 may be similar to the de-bonding process of the first temporary carrier 51 described in FIG. 2E. After the de-bonding of the second temporary carrier 53, the resulting structure may be placed on a tape 54 (e.g., a dicing tape) which is supported by a frame 55 (e.g., a dicing frame). For example, the surface 180a of the second encapsulant 180 and the rear surface(s) 170r of the third semiconductor die(s) 170 (if exposed by the second encapsulant 180) are attached to the tape 54. In some embodiments, the resulting structure is formed in the wafer level, and a singulation process (e.g., laser dicing, sawing, and/or the like) may be performed along scribe lines (not shown) to divide the resulting structure into individual first package components 101.

In some embodiments, the first package component 101 is viewed as a chip-on-wafer (CoW) package. The respective first package component 101 may include a singulated sidewall 101S which includes the sidewall 180S of the second encapsulant 180, the sidewall 160S of the second redistribution structure 160, the sidewall 150S of the first encapsulant 150, and the sidewall 110S of the first redistribution structure 110. In some embodiments, the first and second redistribution structures (110 and 160), the TMVs 120, the first and second semiconductor dies (130 and 140), the first encapsulant 150, and the conductive terminals (190; optional) are collectively viewed as an interposer 1011 (e.g., organic interposer) of the first package component 101.

Referring to FIG. 2H with reference to FIG. 2G, the first package component 101 is optionally bonded to a second package component 102 through the conductive terminals 190. The second package component 102 may be a circuit substrate or a package substrate, such as a printed circuit board (PCB), an organic substrate, a ceramic substrate, a motherboard, or the like. The second package component 102 may be used to interconnect the first package component 101 with other packages/devices to form functional circuits. The second package component 102 has a first side 102a bonded to the first package component 101 and a second side 102b opposite to the first side 102a. In some embodiments, the second package component 102 includes external terminals 1021 formed on the second side 102b. The external terminals 1021 may be BGA connectors, solder balls, metal pillars, C4 bumps, micro bumps, ENEPIG formed bumps, or the like. The dimension of the respective external terminal 1021 may be greater than that of the respective conductive terminal 190.

In some embodiments, the conductive terminals 190 of the first package component 101 are placed on the first side 102a of the second package component 102, and a reflow process may be performed on the conductive terminals 190, thereby coupling the first package component 101 to the second package component 102. In some embodiments, a second underfill 1022 is formed in a gap between the first package component 101 and the second package component 102 to surround the conductive terminals 190. In some embodiments, the second underfill 1022 extends upward to cover at least a lower portion of the sidewall 101S of the first package component 101. Alternatively, the second underfill 1022 is omitted. In some embodiments, the structure shown in FIG. 2H may be a semiconductor package 10 which can be viewed as a three-dimensional integrated circuit (3DIC) package or a CoWoS package. The semiconductor package 10 may be used in a variety of applications. Example systems for the semiconductor package 10 include AI servers, high-performance computing (HPC) systems, high power computing devices, cloud computing systems, and/or the like.

The semiconductor package 10 includes a plurality of third semiconductor dies (170A, 170B, 170C; e.g., heterogeneous dies) electrically coupled to the interposer 1011, and the interposer 1011 may include passive devices (e.g., the capacitor 145 in the second semiconductor die 140) and active circuits (e.g., the active devices in the first semiconductor die 130) integrated together to enhance the signal and power integrity and to lower power consumptions. The first semiconductor die 130 may be a bridge die (e.g., local silicon interconnect die) which functions as an interconnecting structure for the third semiconductor dies (170A, 170B, and 170C), provides shorter electrical connection path the third semiconductor dies (170A, 170B, and 170C), and provides a die-to-die fine line connection arrangement for the third semiconductor dies (170A, 170B, and 170C). The second semiconductor die 140 may (or may not) act as a bridge die.

The second semiconductor die 140 may include the capacitor 145 (e.g., DTC). Because the DTC may provide superior performance and higher capacitance per unit area than normal capacitors, the short transmission path for the electrons from the third semiconductor dies 170 to the second semiconductor die 140 having the capacitor 145 may have better efficiency. The capacitor 145 may be embedded in the second semiconductor substrate 141 and may be disposed in proximity to the front side 141a (labeled in FIG. 1B) of the second semiconductor substrate 141. The second semiconductor die 140 includes the back side coupled to the second redistribution structure 150 and the front side coupled to the first redistribution structure 110 through the second conductive joints 144. In this manner, during the forming process (e.g., the planarization process described in FIG. 2C) of the first encapsulant 150, the second semiconductor substrate 141 may protect the capacitor 145 from the damage that may occur in the planarization process.

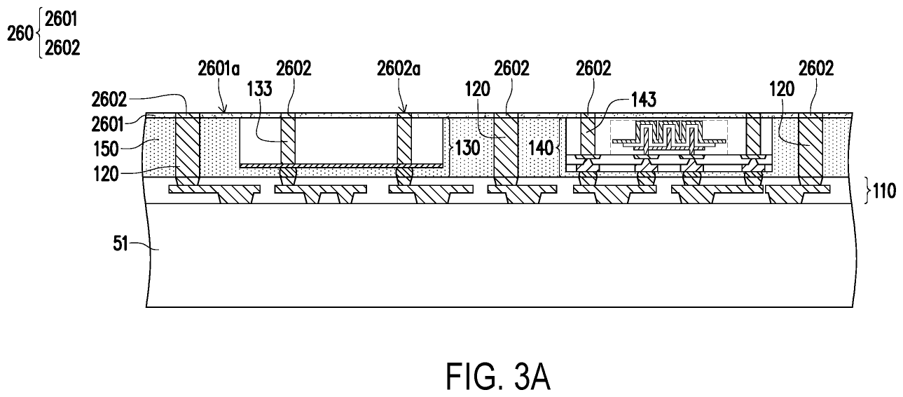

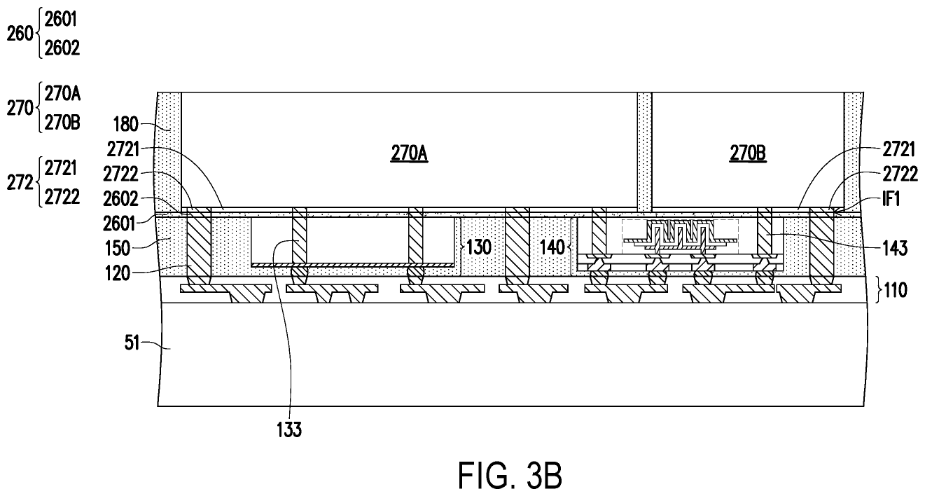

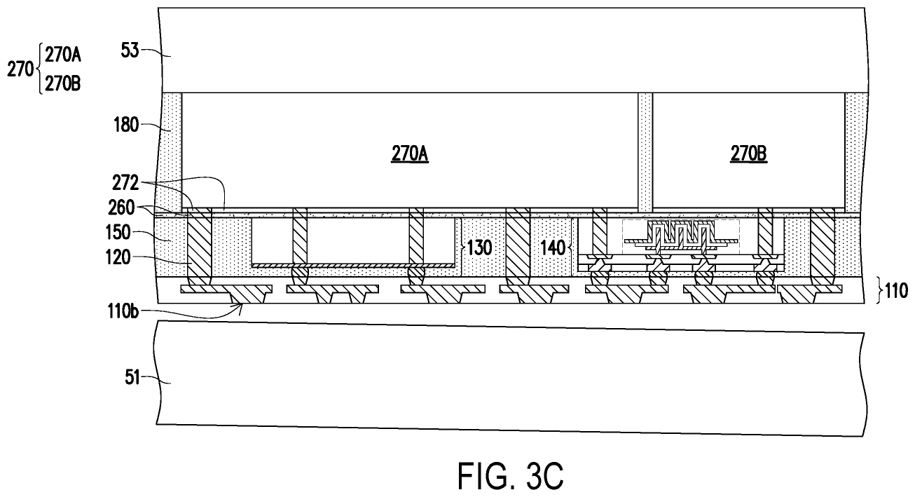

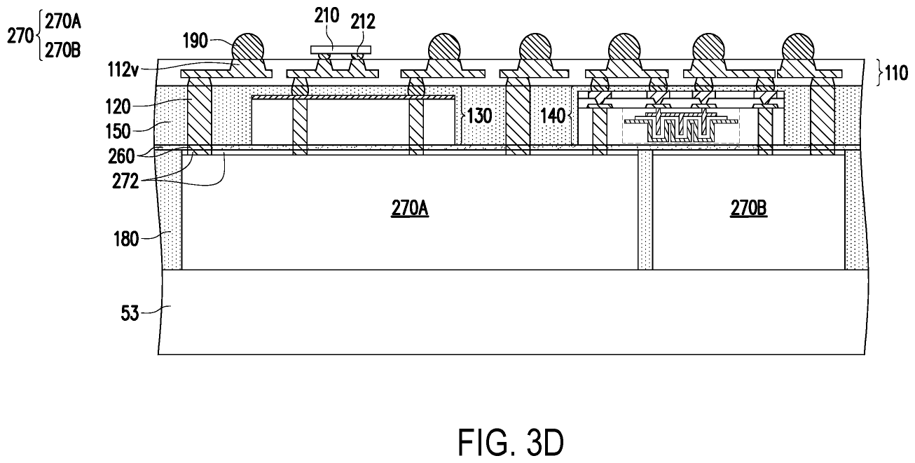

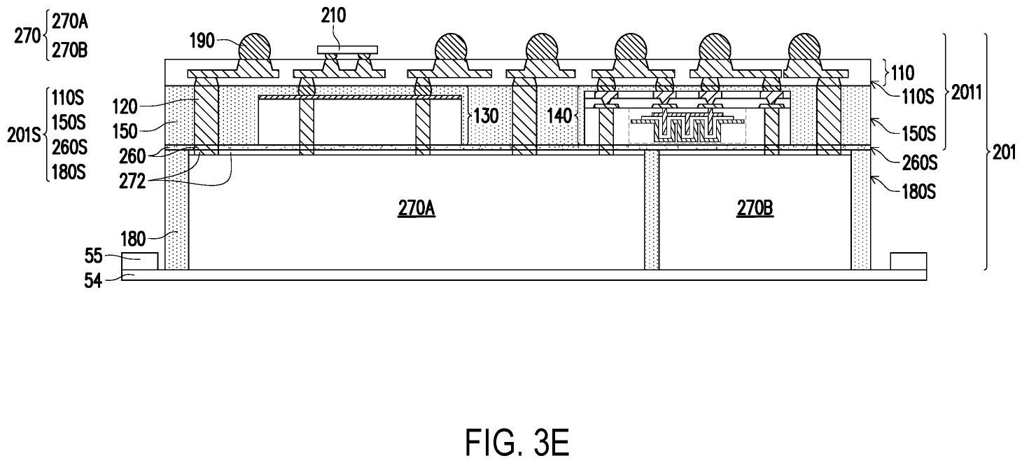

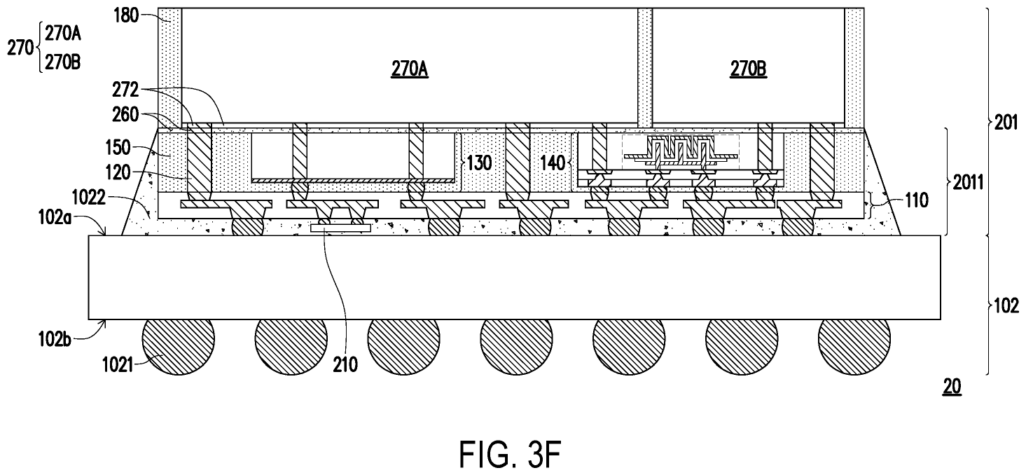

FIGS. 3A and 3F illustrate schematic cross-sectional views of intermediate steps during a process for forming a semiconductor package, in accordance with some embodiments. Unless specified otherwise, the materials and the formation methods of the components in these embodiments are essentially the same as the like components, which are denoted by like reference numerals in the embodiments shown in FIGS. 1G through 2H.

Referring to FIG. 3A and with reference to FIG. 2C, in some embodiments, after forming the first encapsulant 150 as described in FIG. 2C, a first bonding structure 260 may be formed on the first encapsulant 150, the TMVs 120, and the first and second semiconductor dies (130 and 140). The first bonding structure 260 may include a first bonding dielectric layer 2601 and first bonding features 2602 laterally covered by the first bonding dielectric layer 2601. The first bonding dielectric layer 2601 may include a single dielectric material or may include more than one bonding sublayer. The materials of the first bonding dielectric layer 2601 may be or include silicon oxide, silicon oxynitride, silicon nitride, borosilicate (BSG), phosphoric silicate glass (PSG), borophosphosilicate glass (BPSG), fluorinated silicate glass (FSG), a combination thereof, and/or any suitable dielectric material. The first bonding features 2602 may be formed through any suitable formation process (e.g., lithography and etching, damascene, or the like) and may be formed using suitable conductive material(s) such as copper, aluminum, metal alloys, a combination thereof, and/or the like. The respective first bonding feature 2602 may be provided in a via form, a pad form, a combination thereof, etc. In some embodiments, the first bonding features 2602 are physically and electrically connected to the TMVs 120, the first TSVs 133, and the second TSVs 143. A planarization process may be performed on the first bonding structure 260 so that the bonding surface 2601a of the first bonding dielectric layer 2601 may be substantially leveled (or coplanar) with the bonding surfaces 2602a of the first bonding features 2602, within process variations.

Referring to FIG. 3B and with reference to FIG. 3A and FIG. 2D, third semiconductor dies 270 (e.g., 270A and 270B) may be disposed on and bonded to the first bonding structure 260. The respective third semiconductor die 270 may be or include a logic die (e.g., CPU, GPU, SoC, AP, microcontroller, etc.), a memory die (e.g., HBM die, HMC die, DRAM die, SRAM die, etc.), a power management die, a RF die, a sensor die, a MEMS die, a signal processing die (e.g., DSP die), a front-end die (e.g., AFE dies), a voltage regulator die, a combination thereof, and/or the like. The third semiconductor dies (270A and 270B) may be the same type of die or may be different types of dies. In an embodiment, the third semiconductor die 270A is a logic die (e.g., a SoC die) and the third semiconductor die 270B is a memory die. In an embodiment, both of the third semiconductor dies (270A and 270B) are system-on-integrated-circuit (SoIC) dies, and the first semiconductor die 130 electrically coupled to the third semiconductor die 270A is a SoC die, where the SoIC die including the integrated circuit (not shown) can provide an entire system in one IC. The SoIC/SoC dies may provide the circuitry needed to implement a mobile phone, personal data assistant (PDA), digital camera, MP3 player, or the like in a single integrated circuit. It should be noted that although the number of the third semiconductor dies 170 may vary depending on the product requirements.

The third semiconductor dies 270 may be electrically coupled to the TMVs 120 and the first and second semiconductor dies (130 and 140) through the first bonding structure 260. For example, the respective third semiconductor die 270 includes a second bonding structure 272 that is bonded to the first bonding structure 260. The second bonding structure 272 may include a second bonding dielectric layer 2721 and second bonding features 2722 laterally covered by the second bonding dielectric layer 2721. The second bonding dielectric layer 2721 may be similar to the first bonding dielectric layer 2601, and the second bonding features 2722 may be similar to the first bonding features 2602. In some embodiments, the second bonding dielectric layer 2721 is fused to the first bonding dielectric layer 2601, and the second bonding features 2722 are bonded to the first bonding features 2602 in a one-to-one correspondence.

In some embodiments, to facilitate the bonding process, a surface preparation step (e.g., a removal process, an activation process, a cleaning process, and/or the like) is adapted to prepare the bonding surfaces of the first and second bonding structures (260 and 272). For example, the surface preparation step is used to remove a portion of or all of the oxide material(s) on the first and second bonding features 2602 and 2722. After the surface preparation step, the bonding surface of the first bonding structure 260 may be bonded to the bonding surface of the second bonding structure 272. The bonding may be achieved by aligning the first bonding features 2602 with the second bonding features 2722. After the alignment, the second bonding structure 272 of the respective third semiconductor die 270 may be placed on and in direct contact with the first bonding structure 260. When the second bonding dielectric layer 2721 is in physical contact with the first bonding dielectric layer 2601, the first and second bonding dielectric layers (2601 and 2721) may be pre-bonded. After the pre-bonding, the second bonding features 2722 may be in physical contact with the corresponding first bonding features 2602.

In some embodiments, after the pre-bonding, a treatment for dielectric bonding and metal bonding is performed to form bonds at the bonding interface IF1. The bonds may include dielectric-to-dielectric bonds (e.g., oxide-to-oxide bonds) and metal-to-metal bonds (e.g., copper-to-copper bonds). In some embodiments, metal-to-dielectric bonds (e.g., copper-to-oxide bonds) are also formed at the bonding interface IF1. The bonding interface IF1 may be substantially flat (or planar) and smooth, and may be free of solder material. After the bonding, the first and second bonding features (2602 and 2722) may provide vertical and electrical connections in the resulting bonded structure. For example, the third semiconductor die 270A is electrically coupled to the first TSVs 133 of the first semiconductor die 130 directly through the first and second conductive features (2602 and 2722). Similarly, the third semiconductor die (270A and/or 270B) may be electrically coupled to the second TSVs 143 of the second semiconductor die 140 directly through the first and second conductive features (2602 and 2722).

With continued reference to FIG. 3B and FIG. 2D, the second encapsulant 180 may be formed on the first bonding structure 260 to cover the third semiconductor dies 270. The forming process and the material of the second encapsulant 180 may be similar to the second encapsulant 180 described in FIG. 2D. The second encapsulant 180 may be vertically and spatially separated from the first encapsulant 150 at least through the first bonding dielectric layer 2601 of the first bonding structure 260.

Referring to FIG. 3C and with reference to FIG. 3B and FIG. 2E, the first temporary carrier 51 may be de-bonded from the first redistribution structure 110 to accessibly expose the second side 110b of the first redistribution structure 110. The de-bonding process of the first temporary carrier 51 may be similar to the process described in FIG. 2E. The second temporary carrier 53 may be bonded to the second encapsulant 180 and the third semiconductor dies 270 (if exposed by the second encapsulant 180). The bonding process of the second temporary carrier 53 may be similar to the process described in FIG. 2E.

Referring to FIG. 3D and with reference to FIG. 3C and FIG. 2F, the conductive terminals 190 may be formed on the outermost conductive pattern 112v of the first redistribution structure 110. The forming process and the material of the conductive terminals 190 may be similar to those of the conductive terminals 190 described in FIG. 2F. In some embodiments, one or more fourth semiconductor die(s) 210 may be mounted on the outermost conductive pattern 112v of the first redistribution structure 110 through fourth conductive joints 212 (e.g., solder joints). For example, the fourth semiconductor die 210 is surrounded by the conductive terminals 190 and may be electrically coupled to the first and/or second semiconductor dies (130/140) through the first redistribution structure 110. In some embodiments, the fourth semiconductor die 210 is electrically coupled to the third semiconductor die(s) 210 at least through the first redistribution structure 110 and the TMVs 120. The fourth semiconductor die 210 may be or include IPD, surface mount device (SMD), or other suitable package device. Alternatively, the fourth semiconductor die 210 is omitted.

Referring to FIG. 3E and with reference to FIG. 3D and FIG. 2G, the second temporary carrier 53 may be de-bonded from the overlying structure. After the de-bonding of the second temporary carrier 53, the resulting structure may be placed on the tape 54 which is supported by the frame 55. In some embodiments, the resulting structure is formed in the wafer level, and a singulation process (e.g., laser dicing, sawing, and/or the like) may be performed along scribe lines (not shown) to divide the resulting structure into individual first package components 201. The processes may be similar to the process described in FIG. 2G. In some embodiments, the respective first package component 201 includes a singulated sidewall 201S which includes the sidewall 180S of the second encapsulant 180, the sidewall 260S of the first bonding structure 260, the sidewall 150S of the first encapsulant 150, and the sidewall 110S of the first redistribution structure 110. In some embodiments, the first redistribution structure 110, the first bonding structure 260, the TMVs 120, the first and second semiconductor dies (130 and 140), the first encapsulant 150, and the conductive terminals (190; optional) are collectively viewed as an interposer 2011 (e.g., organic interposer) of the first package component 201.

Referring to FIG. 3F and with reference to FIG. 3E and FIG. 2H, the first package component 201 is optionally bonded to the second package component 102 through the conductive terminals 190, and the second underfill 1022 is optionally formed in a gap between the first package component 201 and the second package component 102 to surround the conductive terminals 190. The processes may be similar to the processes described in FIG. 2H. In some embodiments, the structure shown in FIG. 3F is a semiconductor package 20. The third semiconductor dies 270 may be bonded to the interposer 2011 through directly metal-to-metal and dielectric-to-dielectric bonding, and the bonding interface of the third semiconductor dies 270 and the interposer 2011 may be free of solder material. In this manner, the signal paths between the third semiconductor dies 270 and the interposer 2011 may be shorter than those in a traditional 3DIC in which different dies are bonded together using interconnection schemes (e.g., wire bonding or solder bonding). Such bonding scheme of the semiconductor package 20 may allow improved signal integrity and/or power integrity.

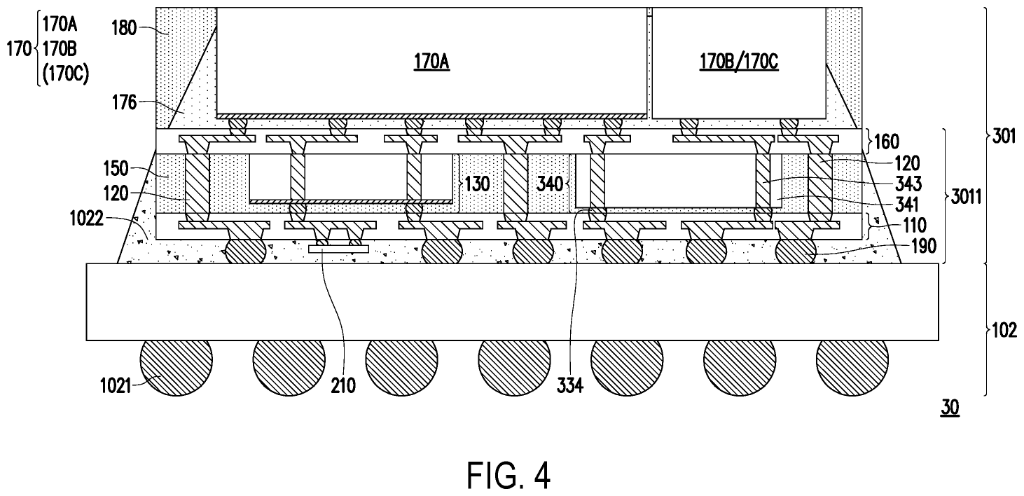

FIG. 4 illustrates a schematic cross-sectional view of a semiconductor package, in accordance with some embodiments. Unless specified otherwise, like reference numerals in the present embodiment represent like components in the embodiment shown in FIGS. 2H and 3F. Referring to FIG. 4 and with reference to FIGS. 2H and 3F, a semiconductor package 30 is similar to the semiconductor package 10 shown in FIG. 2H and the semiconductor package 20 shown in FIG. 3F. The difference includes that the first package component 301 of the semiconductor package 30 includes at least two types of the third semiconductor dies 170 (e.g., 170A and 170B, or 170A and 170C) stacked over the first and second semiconductor dies (130 and 340). In an embodiment, the third semiconductor die 170A is a SoC die, and the third semiconductor die 170B/170C is a memory/DTC die. In an embodiment, the third semiconductor die 170A and the first semiconductor die 130 are SoC dies, where the dimension (e.g., the thickness, the length, and/or the width) of the third semiconductor die 170A is greater than that of the first semiconductor die 130.

The second semiconductor die 340 may include a second semiconductor substrate 341 and second TSVs 343 penetrating through the second semiconductor substrate 341. The second semiconductor substrate 341 and the second TSVs 343 may be similar to the first semiconductor substrate 141 and the first TSVs 143 (described in FIG. 1A), respectively. The second semiconductor die 340 may be a bridge die (e.g., local silicon interconnect die) which functions as an interconnecting structure for the third semiconductor dies (170A and 170B/170C), provides shorter electrical connection path the third semiconductor dies (170A and 170B/170C), and provides a die-to-die fine line connection arrangement for the third semiconductor dies (170A and 170B/170C). The second semiconductor die 340 may be free of active/passive devices. The first package component 301 of the semiconductor package 30 may include one or more fourth semiconductor die(s) 210 mounted on the first redistribution structure 110 of the interposer 3011 and surrounded by the conductive terminals 190. In alternative embodiments, the fourth semiconductor die 210 is omitted. The semiconductor package 30 includes a plurality of heterogeneous dies (e.g., 130, 340, 170) integrated together to enhance the signal/power integrity and increase design flexibility.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

According to some embodiments, a semiconductor package includes an interposer including a first redistribution structure, a first semiconductor die electrically coupled to the first redistribution structure through conductive joints, and a first encapsulant disposed on the first redistribution structure and laterally covering the first semiconductor die. The first semiconductor die includes a semiconductor substrate including a first side facing the first redistribution structure and a second side opposite to the first side, a through substrate via provided within the semiconductor substrate, and a passive device disposed between the second side of the semiconductor substrate and the conductive joints.

According to some alternative embodiments, a semiconductor package includes an interposer and at least one second semiconductor die disposed over and electrically coupled to the interposer. The interposer includes a first redistribution structure, a first semiconductor die, conductive joints, and a molding layer. The first semiconductor die includes a first side, a second side opposite to the first side, a sidewall connected to the first side and the second side, and a capacitor disposed between the first and second sides. The conductive joints couple the first side of the first semiconductor die to the first redistribution structure, and the molding layer extends along the sidewall of the first semiconductor die.

According to some alternative embodiments, a manufacturing method of a semiconductor package includes forming an interposer and coupling at least one second semiconductor die to the interposer. Forming the interposer includes: coupling a first semiconductor die to a first redistribution structure through conductive joints, wherein the first semiconductor die includes a first side to which the conductive joints are connected, a second side opposite to the first side, a TSV extending from the first side to the second side, and a capacitor disposed between the first and second sides; and forming a molding layer on the first redistribution structure to cover the first semiconductor die, wherein when forming the molding layer, a planarization process is performed on the second side of the first semiconductor die and the molding layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
an interposer comprising:
a first redistribution structure;
a first semiconductor die electrically coupled to the first redistribution structure through conductive joints, the first semiconductor die comprising:
a semiconductor substrate comprising a first side facing the first redistribution structure and a second side opposite to the first side;
a through substrate via (TSV) provided within the semiconductor substrate; and
a passive device disposed between the second side of the semiconductor substrate and the conductive joints; and
a first encapsulant disposed on the first redistribution structure and laterally covering the first semiconductor die.

2. The semiconductor package of claim 1, wherein the passive device is a deep trench capacitor, and conductive contacts of the deep trench capacitor are disposed in proximity to the first side and distal from the second side of the semiconductor substrate.

3. The semiconductor package of claim 1, wherein the conductive joints are solder joints.

4. The semiconductor package of claim 1, further comprising:
at least one second semiconductor die stacked upon the interposer and electrically coupled to the first semiconductor die, wherein the interposer further comprises:
a second redistribution structure disposed on the first semiconductor die and the first encapsulant and disposed below the at least one second semiconductor die, wherein the at least one second semiconductor die is electrically coupled to the TSV of the first semiconductor die through the second redistribution structure.

5. The semiconductor package of claim 4, wherein the TSV of the first semiconductor die extends from the first side to the second side of the semiconductor substrate, and a conductive via of the second redistribution structure directly lands on the TSV of the first semiconductor die.

6. The semiconductor package of claim 1, further comprising:
at least one second semiconductor die stacked upon the interposer and electrically coupled to the first semiconductor die, wherein the interposer further comprises:
a first bonding structure disposed on the first semiconductor die and the first encapsulant, the first bonding structure comprising a first bonding dielectric layer and first bonding features, wherein the at least one second semiconductor die comprises a second bonding structure comprising a second bonding dielectric layer and second bonding features, the first bonding dielectric layer is fused to the second bonding dielectric layer, and the first bonding features are bonded to the second bonding features.

7. The semiconductor package of claim 6, wherein the first bonding dielectric layer is substantially leveled with the first bonding features, and the second bonding dielectric layer is substantially leveled with the second bonding features.

8. The semiconductor package of claim 6, further comprising:
a second encapsulant covering the at least one second semiconductor die, wherein the first bonding dielectric layer is interposed between the first encapsulant and the second encapsulant.

9. The semiconductor package of claim 1, wherein the first encapsulant is a molding layer directly and laterally covering the conductive joints.

10. The semiconductor package of claim 1, wherein a surface of the first encapsulant is substantially leveled with the second side of the semiconductor substrate and a surface of the TSV.

11. A semiconductor package, comprising:
an interposer comprising:
a first redistribution structure;
a first semiconductor die comprising a first side, a second side opposite to the first side, a sidewall connected to the first side and the second side, and a capacitor disposed between the first and second sides;
conductive joints coupling the first side of the first semiconductor die to the first redistribution structure;
a molding layer extending along the sidewall of the first semiconductor die; and
at least one second semiconductor die disposed over and electrically coupled to the interposer.

12. The semiconductor package of claim 11, wherein the interposer further comprises:
a second redistribution structure disposed on the second side of the first semiconductor die and the first encapsulant, wherein conductive vias of the second redistribution structure directly land on through substrate vias of the first semiconductor die at the second side of the first semiconductor die.

13. The semiconductor package of claim 11, wherein a bonding interface of the at least one second semiconductor die and the interposer is free of solder material.

14. The semiconductor package of claim 11, wherein the at least one second semiconductor die comprises a first die and a second die, and the first semiconductor die is directly below both of the first die and the second die and interconnects the first die and the second die.

15. The semiconductor package of claim 11, wherein the interposer further comprises:
conductive terminals landing on conductive vias of the first redistribution structure, wherein the conductive joints and the conductive terminals are disposed at two opposing sides of the first redistribution structure.

16. The semiconductor package of claim 11, wherein the capacitor is a deep trench capacitor, and conductive contacts of the deep trench capacitor are disposed in proximity to the first side and distal from the second side of the first semiconductor die.

17. A manufacturing method of a semiconductor package, comprising:
forming an interposer comprising:
coupling a first semiconductor die to a first redistribution structure through conductive joints, wherein the first semiconductor die includes a first side to which the conductive joints are connected, a second side opposite to the first side, a through substrate via (TSV) extending from the first side to the second side, and a capacitor disposed between the first and second sides; and
forming a molding layer on the first redistribution structure to cover the first semiconductor die, wherein when forming the molding layer, a planarization process is performed on the second side of the first semiconductor die and the molding layer; and
coupling at least one second semiconductor die to the interposer.

18. The manufacturing method of claim 17, wherein after the planarization process, the TSV is exposed by a semiconductor substrate of the first semiconductor die, and the capacitor remains buried in the semiconductor substrate.

19. The manufacturing method of claim 17, wherein forming the interposer further comprises:
forming a second redistribution structure on the molding layer and the first semiconductor die, wherein a conductive via of the second redistribution structure directly land on the TSV.

20. The manufacturing method of claim 17, wherein:
forming the interposer further comprises forming a first bonding structure on the molding layer and the first semiconductor die, wherein the first bonding structure comprises a first bonding dielectric layer and first bonding features laterally covered by the first bonding dielectric layer; and
coupling the at least one second semiconductor die to the interposer comprises bonding a second bonding dielectric layer of a second bonding structure of the at least one second semiconductor die to the first bonding dielectric layer and bonding second bonding features of the second bonding structure of the at least one second semiconductor die to the first bonding features.
